(19) United States
(12) Patent Application Publication
(10) Pub. No.: US 2021/0167112 A1
(43) Pub. Date: Jun. 3, 2021

(54) FANOUT WAFER LEVEL PACKAGE FOR OPTICAL DEVICES AND RELATED METHODS

(71) Applicant: SEMICONDUCTOR COMPONENTS INDUSTRIES, LLC, Phoenix, AZ (US)

(72) Inventors: Yusheng LIN, Phoenix, AZ (US); Takashi NOMA, OTA (JP)

(73) Assignee: SEMICONDUCTOR COMPONENTS INDUSTRIES, LLC, Phoenix, AZ (US)

(21) Appl. No.: 16/701,533

(22) Filed: Dec. 3, 2019

(51) Int. Cl. H01L 27/146

(52) U.S. Cl. CPC H01L 27/14634; H01L 27/14627; H01L 27/1469; H01L 27/14618; H01L 27/14636; H01L 27/14621

(57) ABSTRACT

Implementations of semiconductor packages may include: a substrate having a first side and a second side. The package may include a semiconductor package and a controller device coupled to the first side of the substrate through a tape or an adhesive. A molding compound may encapsulate the semiconductor device and the controller device. The package may also include a redistribution layer electrically coupling the semiconductor device and the controller device. An interconnect structure may be coupled with the redistribution layer. The package may include a solder resist layer coupled around the interconnect structure and over the molding compound, the semiconductor device, the controller device, and the copper redistribution layer.

### BACKGROUND

### 1. Technical Field

Aspects of this document relate generally to semiconductor packages, such as wafer level packages for optical devices. More specific implementations involve fanout wafer level packages for camera devices.

### 2. Background

Semiconductor packages are used to enable semiconductor die to be coupled with motherboards and other electrical connections. Semiconductor packages also are used to protect semiconductor die from contamination and from environmental influences during operation.

### SUMMARY

Implementations of semiconductor packages may include: a substrate having a first side and a second side. The package may include a semiconductor device and a controller device coupled to the first side of the substrate through a tape or an adhesive. A molding compound may encapsulate the semiconductor device and the controller device. The package may also include a redistribution layer electrically coupling the semiconductor device and the controller device. An interconnect structure may be coupled with the redistribution layer. The package may include a solder resist layer coupled around the interconnect structure and over the molding compound, the semiconductor device, the controller device, and the copper redistribution layer.

Implementations of semiconductor packages may include one, all, or any of the following:

The substrate may include an optically transmissive material.

The semiconductor package may further include a second and a third copper redistribution layer.

The redistribution layer may be copper.

The semiconductor device may be an image sensor including a microlens or a color filter.

The semiconductor package may further include a tape or a resin coating on a first side of the substrate.

The semiconductor package may further include nickel gold (NiAu) plating around the interconnect structure.

Implementations of semiconductor packages may include: a semiconductor device including a first side and a second side and a controller device including a first side and a second side. The controller device and the semiconductor device may be in the same plane. The package may also include a molding compound encapsulating the semiconductor device and the controller device. A redistribution layer may electrically couple the semiconductor device and the controller device through two or more pillars on a second side of each of the semiconductor device and the controller device. The package may also include an interconnect structure coupled to the redistribution layer. The package may also include a solder resist layer over the second side of each of the semiconductor device and the controller device.

Implementations of semiconductor packages may include one, all, or any of the following:

The package may further include a substrate coupled to the first side of each of the semiconductor device and the controller device.

The substrate may include an optically transmissive material.

The package may further include a second and a third copper redistribution layer.

The redistribution layer may be copper.

The semiconductor device may include an image sensor including a microlens or a color filter.

The package may further include a tape or a resin coating on a first side of the substrate.

The package may further include nickel gold (NiAu) plating around the interconnect structure.

Implementations of semiconductor packages may be formed using an implementation of a method of forming a semiconductor package, including: providing a substrate. The substrate may include a first side and a second side. The method may include coupling a first side of a semiconductor device to a second side of the substrate. The method may also include coupling a first side of a controller device to a second side of the substrate adjacent to the semiconductor device. The method may include forming a molding compound on the second side of the substrate surrounding the semiconductor device and the controller device. The method may also include etching two or more via through a silicon layer on a second side of each of the semiconductor device and the controller device. The method may include forming two or more pillars in the silicon layer in each of the semiconductor device and the controller device. The method may also include plating a redistribution layer between one of the two or more pillars on each of the semiconductor device and the controller device. The method may include coupling an interconnect structure to the redistribution layer. The method may also include forming an insulation layer over the second side of each of the semiconductor device, the controller device, and the redistribution layer. The method may include dicing the substrate to form a plurality of semiconductor packages each including a semiconductor device and a controller device.

Implementations of methods of forming semiconductor packages may include one, all, or any of the following:

The method may further include removing the substrate from a first side of each of the plurality of semiconductor packages.

The two or more pillars and the redistribution layer may include copper.

Dicing the substrate may further include forming an optically transmissive lid over the semiconductor device and the controller.

The semiconductor device includes an image sensor device.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a semiconductor package;

FIG. 2 is a cross sectional view of an implementation of a semiconductor package coupled with an implementation of a printed circuit board;

FIG. 3 is a cross sectional view of an implementation of a semiconductor package without an implementation of a support substrate;

FIG. 4 is a cross sectional view of an implementation of a semiconductor package with a cavity over an implementation of a image sensor device;

FIG. 5 is a cross sectional view of an implementation of a semiconductor package including metal plating around an implementation of an interconnect structure;

FIG. 6 is a cross section view of an implementation of a semiconductor package coupled with a silicon substrate;

FIG. 7 is a cross section view of an implementation of a semiconductor package coupled with an implementation of a silicon substrate and a resin coating on the silicon substrate;

FIG. 8 is a cross section view of an implementation of a semiconductor device and an implementation controller device coupled on a second side of an implementation of a light transmissive substrate;

FIG. 9 is a cross sectional view of an implementation of a semiconductor package after encapsulation with a molding compound encapsulating;

FIG. 10 is a cross sectional view of an implementation of a semiconductor package after back grinding of the molding compound and the semiconductor device and the controller device;

FIG. 11 is a cross section view of an implementation of a semiconductor package after having implementations of through silicon vias etched in each of the semiconductor device and the controller device;

FIG. 12 is a cross section view of an implementation of a semiconductor package having a photoresist pattern on the implementation of the semiconductor device and the implementation of the controller device;

FIG. 13 is a cross section view of an implementation of a semiconductor package having an implementation of a redistribution layer coupling the implementation of the semiconductor device and the implementation of the controller device;

FIG. 14 is a cross section view of an implementation of a semiconductor package having an implementation of a interconnect structure coupled with the implementation of the redistribution layer and an implementation of a insulation layer over the second side of each of the semiconductor device, the controller device, and the redistribution layer;

FIG. 15 is a cross section view of an implementation of a semiconductor package coupled to an implementation of a printed circuit board;

FIG. 16 is a cross section view of an implementation of a semiconductor device and an implementation controller device coupled on a second side of an implementation of a silicon substrate;

FIG. 17 is a cross sectional view of an implementation of a semiconductor package after encapsulation with a molding compound;

FIG. 18 is a cross sectional view of an implementation of a semiconductor package after back grinding of the molding compound and the semiconductor device and the controller device;

FIG. 19 is a cross section view of an implementation of a semiconductor package having implementations of through silicon vias etched in each of the semiconductor device and the controller device;

FIG. 20 is a cross section view of an implementation of a semiconductor package having a photoresist pattern on the implementation of the semiconductor device and the implementation of the controller device;

FIG. 21 is a cross section view of an implementation of a semiconductor package having an implementation of a redistribution layer coupling the implementation of the semiconductor device and the implementation of the controller device;

FIG. 22 is a cross section view of an implementation of a semiconductor package having an implementation of a interconnect structure coupled with the implementation of the redistribution layer and an implementation of a insulation layer over the second side of each of the semiconductor device, the controller device, and the redistribution layer; and

FIG. 23 is a top view comparison of two implementations of camera modules;

FIG. 24 is a top view of an implementation of a semiconductor package including a controller module and an image sensor device;

FIG. 25 is a cross section view of an implementation of a semiconductor device including only an image sensor device;

FIG. 26 is a top view of an implementation of a semiconductor device including only an image sensor device;

FIG. 27 is a cross section view of an implementation of a semiconductor device including a metal piece on a portion of the image sensor device;

FIG. 28 is a cross section view of an implementation of a semiconductor device including a dark opaque resist resin.

### DESCRIPTION

This disclosure, its aspects and implementations, are not limited to the specific components, assembly procedures or method elements disclosed herein. Many additional components, assembly procedures and/or method elements known in the art consistent with the intended fanout wafer level package optical device will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such fanout wafer level package optical device, and implementing components and methods, consistent with the intended operation and methods.

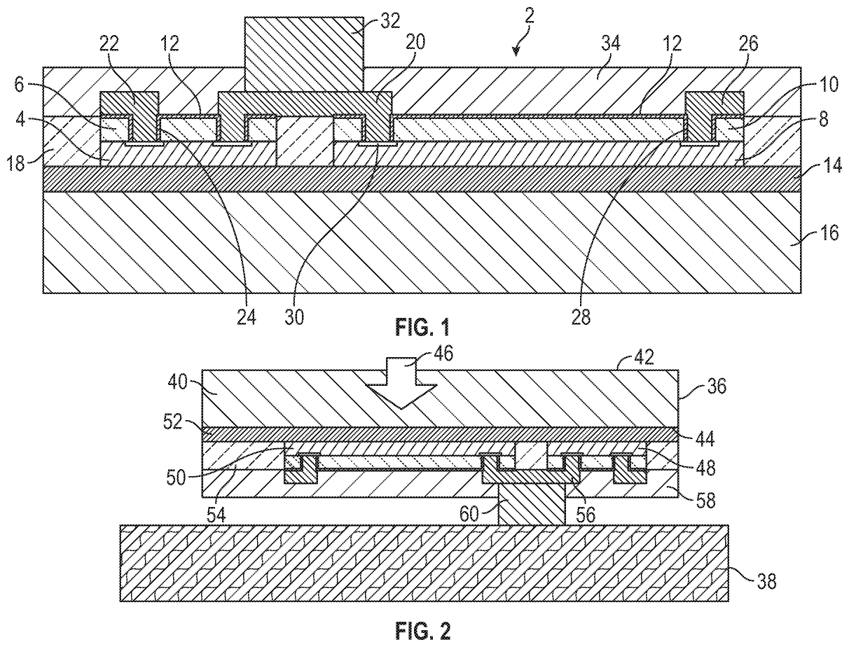

Referring to FIG. 1, an implementation of a semiconductor package 2 is illustrated. The package includes a controller device 4. The controller device 4 may be formed on a silicon substrate 6. The controller device 4 may include large scale integration (LSI) in some implementations. In other implementations, the controller device 4 may be formed on a substrate 6 formed of another material such as gallium nitride. The controller device 4 may have a thickness between about 10 and about 200 microns. The package 2 also includes a semiconductor device 8. In various implementations, the semiconductor device 8 may be an image sensor. The image sensor device may include a complementary metal-oxide-semiconductor (CMOS). In other implementations, the image sensor device may include a charge coupled device (CCD). In some implementations, the image sensor 8 device may be formed on a silicon substrate 10. The image sensor 8 may include a protection layer. The semiconductor device 8 may have a thickness of about 10 to about 200 microns. As illustrated, in various implementations, a layer of polyimide 12 is formed over the second side of each of the substrates of the controller device 4 and the image sensor device 10. In other implementations, another material may be used to provide an electrically insulative/protective layer on the components.

Both the controller device 4 and the semiconductor device 8 are glued/adhered 14 to a glass wafer 16. In other implementations, the controller device 4 and the semiconductor device 8 may be taped to the substrate. In some implementations, the substrate may be formed of an optically transmissive material. In other implementations, the substrate may be formed of silicon or other suitable semiconductor material. The wafer 16 may provide support to the semiconductor package in some implementations. In various implementations, the wafer 16 may have a thickness between about 100 microns and about 400 microns.

Still referring to FIG. 1, the semiconductor package also includes a molding compound 18. As illustrated, the molding compound 18 encapsulates the controller device 4 and the semiconductor device 8. A redistribution layer 20 is formed between the controller 4 device and the semiconductor device 6. The redistribution layer (RDL) 20 is formed of copper in this particular implementations. In other implementations, the RDL must be formed of another electrically conductive material, such as, by non-limiting example, a metal, a metal alloy, aluminum, aluminum copper, silver, gold, or any other electrically conductive material. A second RDL 22 is also formed in a via 24 of the controller device 4. A third RDL 26 is formed in a via 28 of the semiconductor device 4. In some implementations, the RDLs may include a pillar formed in a via and a RDL mechanically and electrically coupled to the pillars. The RDLs/pillars are coupled with an aluminum pad 30 of each of the components. In other implementations, the pad may be formed of another electrically conductive material like any disclosed herein. The RDLs may be formed through a plating process as will be explained in more detail below.

An interconnect structure 32 is coupled to the RDL 20 coupling the controller device 4 and image sensor device 8. The interconnect structure 32 may include a ball grid array. The interconnect device 32 may be formed of an electrically conductive material. In other implementations, the interconnect device may include pillars. The package includes an insulation layer 34 covering the molding compound 18, the RDLs (20, 22, and 26), the controller device 4, the semiconductor device 8 and formed around the interconnect structure 32.

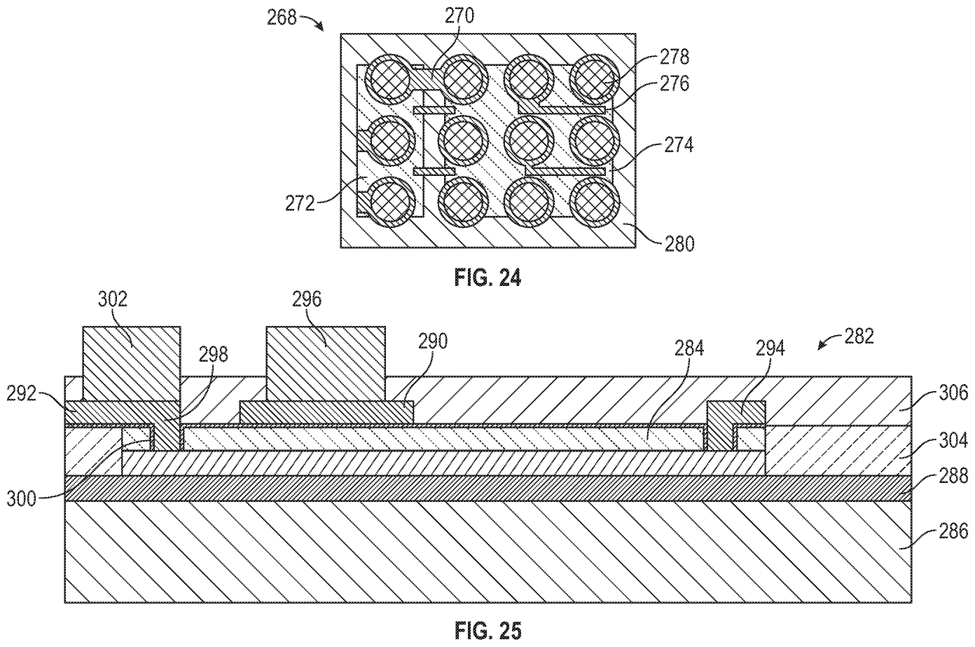

A top view of an implementation of the semiconductor package 268 is illustrated in FIG. 24. In this view, the connections 270 between the controller 272 and the image sensor device 274 are visible. Other connections 276 are visible from this view as well as each of the interconnect structures 278 extending from the second side of each of the controller device 272 and the image sensor device 274. A molding compound 280 encapsulating the devices is also illustrated. The molding compound extends to the edge of the substrate of the semiconductor package 268. In various implementations, the semiconductor may not have a substrate after processing as will be described in further detail below. FIG. 24 may be a representative illustration of any semiconductor package including both a controller device and an image sensor device as described herein. In other implementations, the semiconductor package may include one or more other devices other than controllers and image sensors.

Referring to FIG. 2, an implementation of a semiconductor package 36 coupled with a printed circuit board (PCB) 38 is illustrated. The semiconductor package 36 includes a light transmissive substrate 40. The light transmissive substrate has a first side 42 and a second side 44. The first side 42 is positioned opposite the PCB 38 to allow light 46 into substrate 40. On the second side 44 of the substrate 40 a controller device 48 and an image sensor device 50 are coupled to the substrate 40. The controller device 48 and the image sensor device 50 may be coupled to the substrate 40 through a light transmissive glue, tape, or other suitable adhesive 52. The controller device 48 and the image sensor 50 are encapsulated with a molding compound 54. The controller device 48 and the image sensor 50 are electrically coupled to each other and to other components of device through RDLs 56 formed of a conductive material. In the implementation illustrated in FIG. 2, a solder resist layer 58 is formed over the second side of each of the controller device 48, the semiconductor device 50, and the molding compound 54. An interconnect structure 60 is coupled to the RDL 56 and couples the semiconductor package 36 to the PCB substrate 38. In other implementations, the semiconductor package can be coupled with other devices or substrates through the interconnect structure.

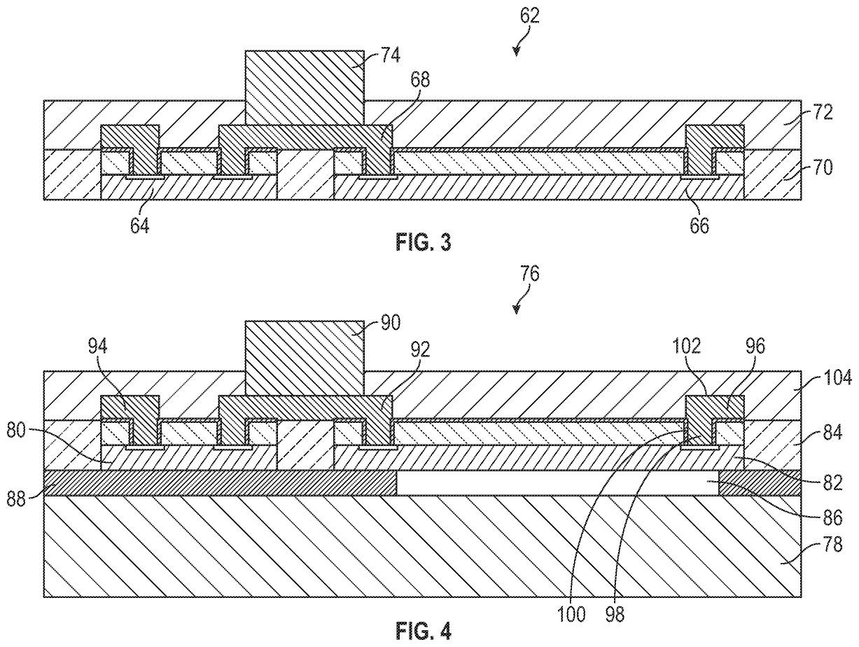

Referring to FIG. 3, another implementation of a semiconductor package 62 is illustrated. This particular implementation of the semiconductor package does not include a support substrate. A controller device 64 and an image sensor device 66 are coupled through a copper RDL 68. In other implementations, the RDL may be formed of other conductive materials. The controller device 64 and the image sensor device 66 are encapsulated with a molding compound 70 and a solder resist 72 is coupled to the molding compound 70 and around an interconnect structure 74.

Referring to FIG. 4, another implementation of a semiconductor package 76 is illustrated. This particular implementation includes a light transmissive substrate 78. A controller device 80 and a semiconductor device 82 are coupled with the substrate 78 with a molding compound 84 encapsulating the controller device 80 and the semiconductor device 82. There is a cavity structure 86 over the image sensor device 82. The image sensor device 82 may include a micro lens or a color filter. The cavity structure 86 is formed in the adhesive 88 between the substrate 78 and the image sensor device 82. A interconnect device 90 is coupled with an RDL 92. The RDL 92 electrically and mechanically couples the controller device 80 with the image sensor device 82. A second RDL 94 is coupled with the controller 80 that extends to other areas of the semiconductor package 76. A third RDL 96 is coupled with the semiconductor device 82. In various implementations, the RDLs may include a pillar 98 formed in a via 100 in each of the components and plating layer 102 coupled with the pillar 98. In the implementation illustrated in FIG. 4, a solder resist layer 104 is coupled over the molding compound 84, the semiconductor device 82, the controller device 80, and the copper RDL 92. The solder resist layer 104 is also coupled around a ball grid array 90 which is coupled with the RDL 92 coupling the image sensor device 82 with the controller 80. In various implementations, another interconnect structure could be used.

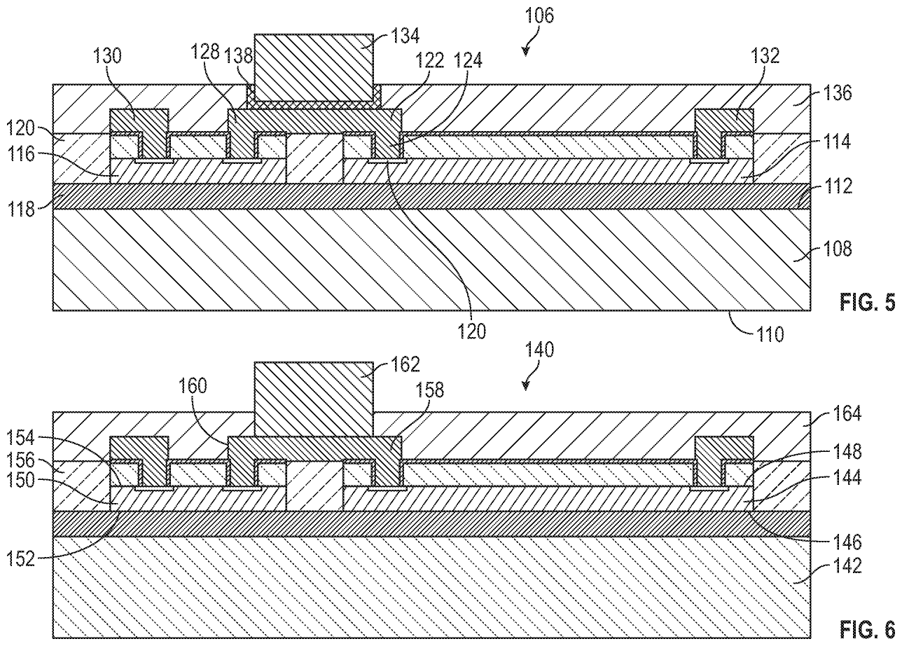

Referring to FIG. 5, another implementation of a semiconductor package 106 is illustrated. The package 106 includes a substrate 108 having a first side 110 and a second side 112. In this implementation, the substrate 108 is made of a light transmissive material such as, by non-limiting example, glass, polymers, and other materials that allow both visible and non-visible light, including infrared (IR) light, to pass through the substrate. In other implementations, the substrate 108 may be made of silicon or other semiconductor materials. The package 106 includes a semiconductor device 114 and a controller device 116 arranged in a same plane. The semiconductor device 114 and the controller device 116 are coupled to the second side 112 of the substrate 108 through an adhesive 118. In various implementations, the adhesive may include, by non-limiting example, a glue, a tape, or other suitable material to couple the devices to the substrate. In some implementations, the coupling of the devices to the substrate may be permanent. In other implementations, the substrate may be peeled or removed at the end of processing manufacturing as illustrated in FIG. 3.

A molding compound 120 is illustrated encapsulating the semiconductor device 114 and the controller device 116. In some implementations, the molding compound 120 may include, by non-limiting example, epoxies, resins, phenolic hardeners, silicas, and combination thereof. As illustrated, an RDL 122 mechanically and electrically couples the semiconductor device 114 with the controller device 116. The RDL 122 may be formed of copper or other electrically conductive materials. In some implementations, the RDL may include one or more pillars 124 coupled with a pad 126 of the controller device 116 or semiconductor device 114 and a metal plating 128 coupled with the pillar 124. A second RDL 130 and third RDL 132 are illustrated coupled individually to the controller device 116 and the semiconductor device 132, respectively. As previously described, the semiconductor device is an image sensor device. However in other implementations, the semiconductor device could include semiconductor devices such as, by non-limiting example, diodes, transistors, and other semiconductor devices.

Still referring to FIG. 5, an interconnect structure 134 is coupled with the copper RDL 122. The interconnect structure 134 may include, by non-limiting example, a ball grid array, individual solder balls, pillars, or other electrically conductive materials used for connecting devices. The interconnect structure 134 may be used to couple the package to a PCB, motherboard, or as a component within another device such as, by non-limiting example, a camera as illustrated in FIG. 2. A solder resist layer 136 coupled around the interconnect structure 134 and over the molding compound 120, the semiconductor device 114, the controller device 116, and the copper RDL 122. In this particular implementation, an under bump metallization (UBM) layer 138 is formed around the interconnect structure 134. The UBM layer 138 may include nickel gold (NiAu) plating. In other implementations, the plating may include a titanium copper (TiCu) sputtering followed by NiAu plating.

Referring to FIG. 6, an implementation of a semiconductor package 140 including a silicon substrate 142 is illustrated. In various implementations, other semiconductor materials may be used for the substrate such as, by non-limiting example, germanium (Ge), Gallium arsenide (GaAs), Silicon carbide (SiC), indium arsenide, indium antimonide, and indium phosphide. The package 140 includes a semiconductor device 144 having a first side 146 and a second side 148 and a controller device 150 having a first side 152 and a second side 154. The controller device 150 and the semiconductor device 144 are coupled to the substrate 142 in the same plane rather than being in a stacked configuration.

Still referring to FIG. 6, the package includes a molding compound 156 encapsulating the semiconductor device 144 and the controller device 150. In various implementations, the molding compound 156 may include an epoxy, a resin, or other suitable material. An RDL 158 is illustrated electrically coupling the semiconductor device 144 and the controller device 150 through two or more pillars 160 on a second side of each of the semiconductor device 144 and the controller device 150. The RDL may be made of gold or other suitable electrically conductive material. An interconnect structure 162 is coupled to the RDL 158 and extends to an outside of the package. The interconnect structure 162 may include a ball grid array, solder balls, pillars, or other structure used to electrically couple semiconductor devices together and/or to a circuit board. The interconnect structure 162 is surrounded by a solder resist layer 164 over the second side of each of the semiconductor device 144 and the controller device 150.

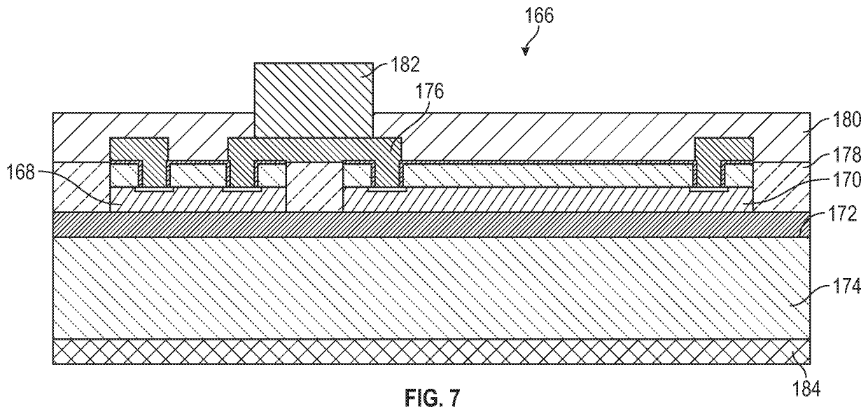

Referring to FIG. 7, an implementation of a semiconductor package 166 is illustrated. The semiconductor package 166 has a similar structure to the other packages described herein. A controller device 168 and a semiconductor device 170 are coupled to a second side 172 of a semiconductor substrate 174. The devices 168 and 170 are electrically coupled through an RDL 176 and are encapsulated by a molding compound 178. A solder resist layer 180 is illustrated covering the second side of each of the semiconductor device 170 and the controller device 168 and the illustrated RDL 176. A ball grid array 182 is coupled with the RDL 176 coupling the devices together. The ball grid array 182 may be used to couple the package to a printed circuit board, motherboard, or other electrical device. In this particular implementation a resin coating 184 is illustrated on a first side of the substrate. In other implementations, another protective material may be formed on the first side of the substrate. In still other implementations, a back side tape may be coupled with the first side of the substrate.

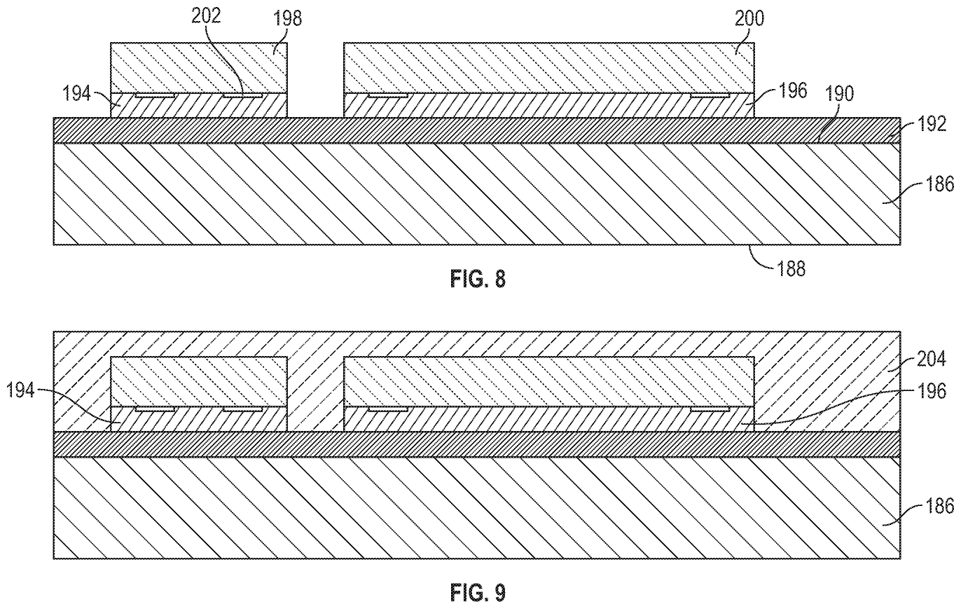

Referring to FIGS. 8-14, an implementation of a method for forming semiconductor packages like those disclosed herein is illustrated. The method may include preparing a silicon substrate 186 having a first side 188 and a second side 190, mounting tape 192 to a second side 190 of the substrate 186 and mounting a controller device 194 and an image sensor device 196 to the substrate 186. The image sensor device 196 may include a complementary metal oxide semiconductor device (CMOS) or a charge coupled device (CCD). Each of the controller 194 device and the image sensor device 196 may include silicon substrates 198 and 200 positioned opposite the substrate 186 of the package. Each device 194 and 196 includes aluminum pads 202 at an interface between the device 194 and the silicon substrate 198. In some implementations, a coating of glue may be added to the second side of the silicon substrate of the package instead of using a mounting tape. In other implementations, other adhesive suitable for semiconductor devices may be used to couple the devices to the substrate. The silicon substrate 186 may have a thickness of 100 to 200 microns in various implementations. In some implementations, the substrate may be made of another semiconductor material such as gallium nitride. Referring to FIG. 8, the controller device 194 and the image sensor device 196 are illustrated coupled with the silicon substrate 186 through an adhesive 192.

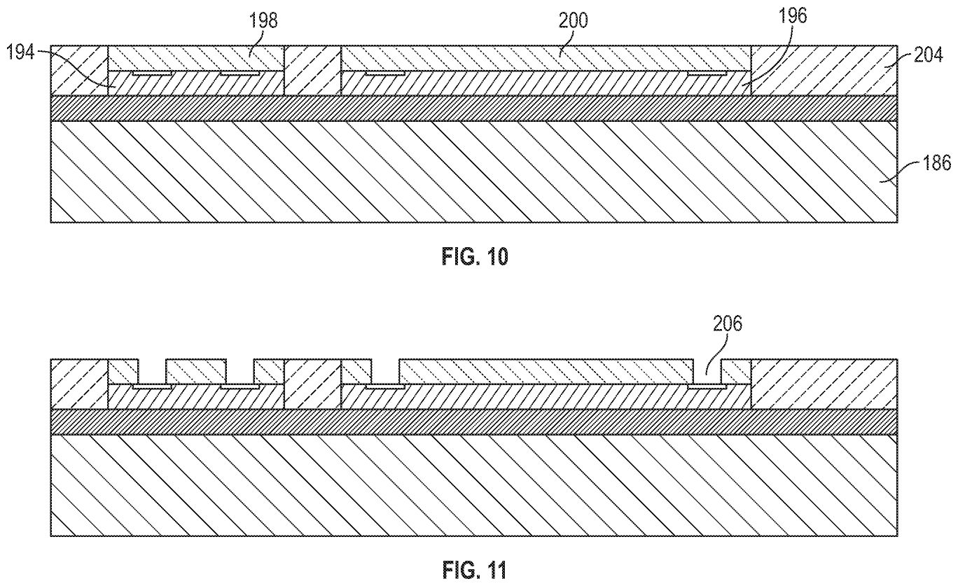

The method may include forming a molding compound 204 around the controller device 194 and the image sensor device 196. As illustrated in FIG. 9, the molding compound fully encapsulates the devices immediately after the molding process. Referring to FIG. 10, the package is illustrated after the molding compound 204 has been back ground to partially remove and expose a surface of the silicon substrate 198 and 200 on each of the controller device 194 and the image sensor device 196, respectively.

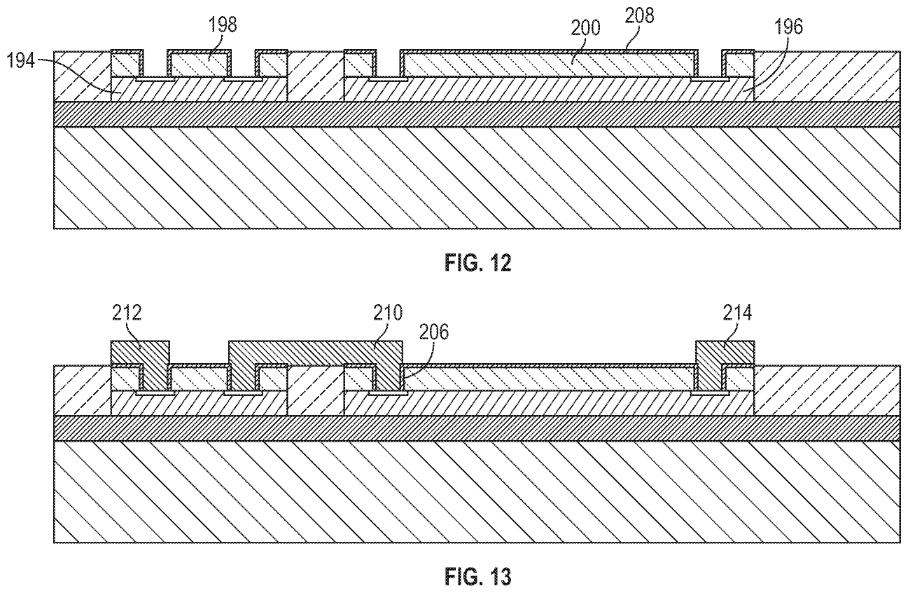

The method further includes aligning the silicon substrate before etching vias in each of the controller device and the image sensor device. The vias are formed in the silicon substrate of the device extending from the second surface of the substrate to the pads in each of the devices. A photoresist layer is added to the devices before etching, patterned, and is removed after etching. Referring to FIG. 12, the package is illustrated after the vias 206 have been formed through silicon and oxide etching processes. The method includes applying a polyimide layer 208 to the substrates 198 and 200 of the devices 194 and 196. In various implementations, other insulative layers may be used. The insulative layer may be formed through chemical vapor distillation (CVD). Referring to FIG. 12, the package is illustrated after formation of the insulative layer 208.

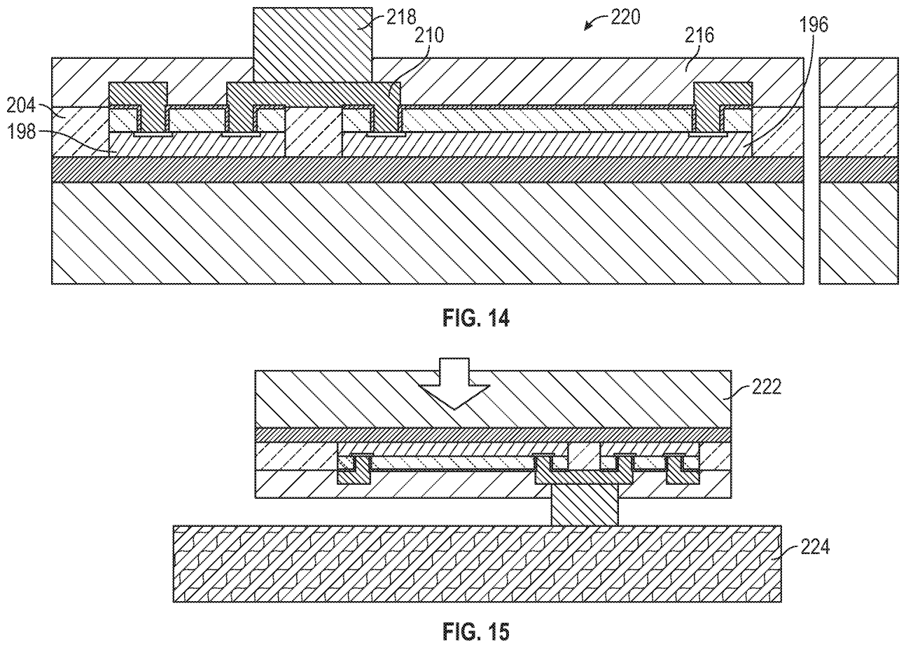

The method further includes forming redistribution layers (RDLs) 210 in the vias 206. The RDLs may be formed through plating. An RDL is formed coupling the controller device 194 with the image sensor device 198. A second RDL 212 and third RDL 214 are formed in each of the devices. In various implementations, the RDL may first include forming pillars in the vias and then forming a plating layer between the pillars. Referring to FIG. 13, the package is illustrated after formation of the RDLs 210, 212, and 214. The method then includes forming a solder resist layer 216 over the second side of each of the semiconductor device 196, the controller device 198, the molding compound 204, and the RDLs. In various implementations, another insulative material besides solder resist may be used. An interconnect structure 219 is formed over the RDL 210 coupling the controller device 198 and the image sensor device 196. The interconnect structure 218 may be formed in an opening of the solder resist 216. In various implementations, the interconnect may include a ball grid array, solder balls, pillars, or any other interconnect structures described herein. The method includes singulating the silicon substrate to form a plurality of semiconductor packages. The packages may be singulated through, by non-limiting example, dicing, sawing, laser cutting, or other suitable methods for singulating semiconductor substrates. Referring to FIG. 14, the semiconductor package 220 is illustrated after singulation.

In various implementations, the method may further include removing a support substrate of the package leaving the devices exposed as illustrated in FIG. 3. The substrate may be removed through peeling. The substrate may be removed before or after singulation of the substrate. In still other implementations, the method may include applying a backside tape to the first side of the silicon substrate. The method may include applying a resin coating as illustrated in FIG. 7. The backside tape or resin coating may be applied before singulation. After the formation of the plurality of semiconductor packages, an individual package 222 may be flipped and coupled with a PCB 224 as illustrated in FIG. 15.

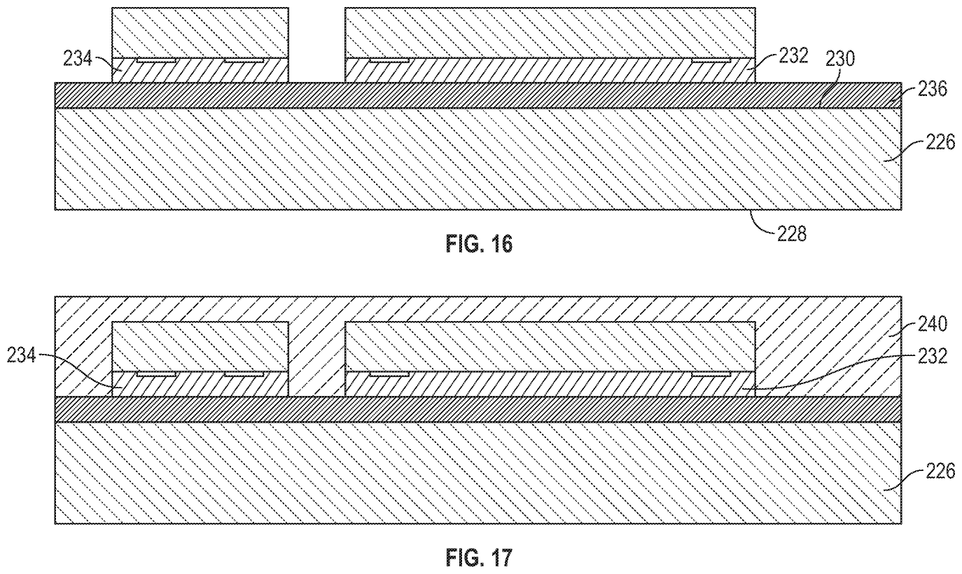

Referring to FIGS. 16-22, another implementation of a method of forming a semiconductor package is illustrated. The method includes providing a substrate 226 having a first a first side 228 and a second side 230. The substrate 226 may include a glass or optically transmissive substrate as illustrated. As previously described, the substrate may be a silicon substrate or other suitable semiconductor material. The method also include preparing an image sensor device 232 and a controller device 234 having a bare chip structure. An adhesive tape or glue 236 is applied to the optically transmissive substrate 226 and the image sensor 232 and controller device 234 are coupled with the substrate 226. Specifically, a first side of the image sensor 232 is coupled to a second side 230 of the substrate 226 and a first side of the controller device 234 is coupled to a second side 230 of the substrate 226 adjacent to the image sensor device 232. As previously described, the methods and packages described herein may be manufactured with semiconductor devices other than image sensors. Referring to FIG. 16, the package is illustrated after the first side of the semiconductor device 232 and the first side of the controller device 234 have been coupled to the second side 230 of the optically transmissive substrate 226 through the adhesive material 236.

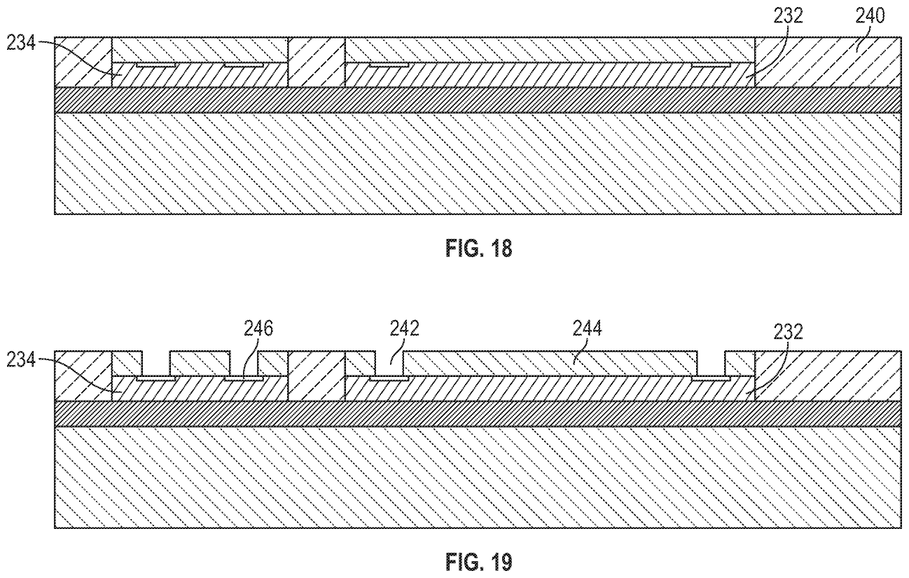

The method also includes applying a molding compound 240 to the substrate 226 encapsulating the devices 232 and 234. The molding compound 240 may be applied through compression molding. Referring to FIG. 17, the package is illustrated after the molding compound 240 has been applied and completely encapsulates each of the devices 232 and 234. The method then includes grinding the molding compound and back side of each of the devices. Grinding may remove from about 10 to about 200 microns of material. Referring to FIG. 18, the package is illustrated after a portion of the molding compound 240 and the second side of the devices 232 and 234 have been removed.

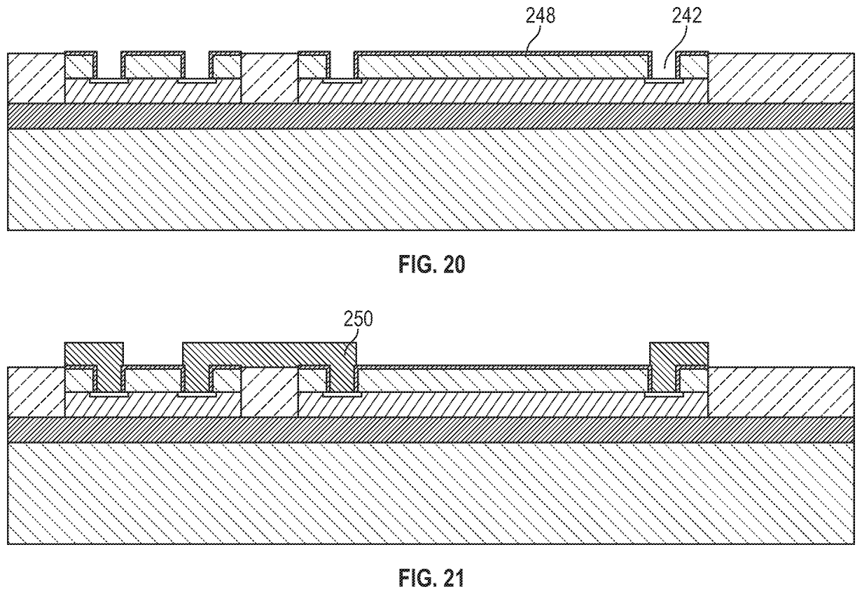

The method then includes forming a photoresist pattern on the second side of the controller device and the image sensor device to prepare for silicon via formation. Two or more vias 242 may be formed through etching of the silicon 244 on each of the controller device 232 and image sensor device 234. The aluminum pads 246 of the device may be exposed through oxide etching. Referring to FIG. 19, the package is illustrated after the vias 242 have been formed. An insulator layer 248 may be formed around the contact hole/via 242 using a photo sensitive resin. The method then includes forming a titanium copper (TiCu) under bump metallization and photoresist pattern then forming one or more RDLs through copper plating. Referring to FIG. 20, the package is illustrated after formation of the insulator layers 248 around the vias 242. In various implementations, the method may include forming two or more pillars in the silicon vias in each of the semiconductor device and the controller device and then plating the redistribution layer between one of the two or more pillars on each of the semiconductor device and the controller device. Referring to FIG. 21, the package is illustrated after formation of the RDLs 250. The photoresist and UBM may be removed by etching chemicals/ashing processes.

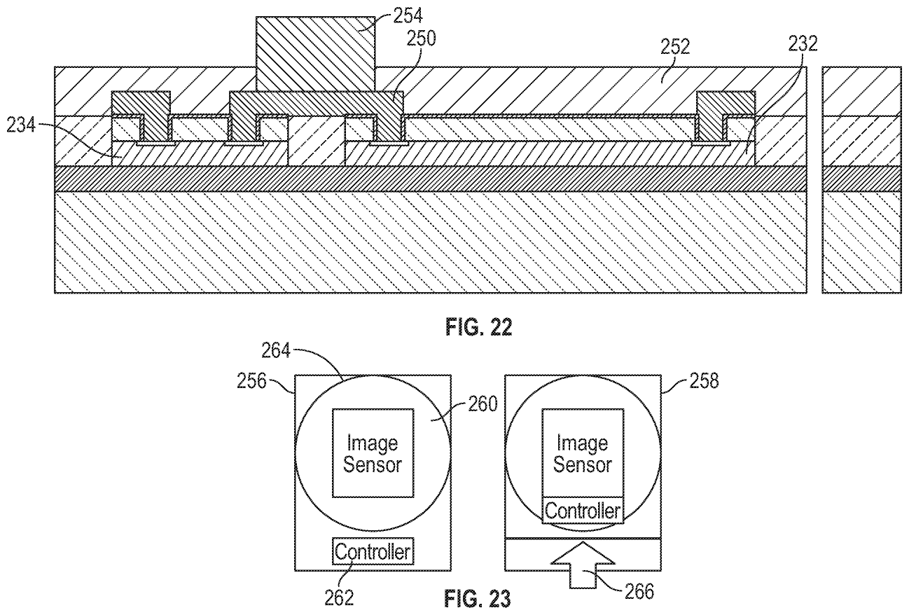

The method also includes forming a second insulator layer 252 over the second side of each of the semiconductor device 232, the controller device 234, and the redistribution layer 250. In various implementations, the insulator layer 252 may be a solder resist. The insulator layer 252 may be formed with an opening to receive the interconnect structure 254. The method then includes forming the interconnect structure 254 in the opening in the insulator layer 252. The interconnect structure 254 is coupled with the RDL 250. In various implementations, the interconnect structure may be a solder bump. The method includes dicing the substrate to form a plurality of semiconductor packages each including a semiconductor device and a controller device. Referring to FIG. 22, the package is illustrated after singulation through dicing. In other implementations, the substrate may be singulated through sawing or laser cutting.

Referring to FIG. 23, a comparison between a first implementation of a camera module 256 and camera modules 258 utilizing a second implementation of a semiconductor package as described herein is illustrated. Current camera modules 256 use two separate chip scale packages (CSP). One CSP is for the image sensor 260 and the other is for the controller device 262. The image sensor CSP 260 is positioned under lens 264 of the camera while the controller CSP 262 is set off to the side. Using implementations of semiconductor packages as described herein with the controller device and the image sensor device packaged within a single semiconductor package, the size of the camera module 258 can be decreased as indicated by arrow 266. Performance of the camera module may also be improved since there is less distance between the image sensor and the controller device. In digital cameras and mobile phones with cameras, image signal processing is performed on raw output from a CCD/CMOSimage sensor. At an image signal processor (ISP), processing on a pixel-by-pixel basis, such as correction processing of an optical system such as a lens or flaw correction caused by variations in an image sensor, etc., is important.

Referring to FIG. 25, another implementation of a semiconductor device 282 is illustrated. This particular implementation includes only one device 284. Here the device 284 illustrated is an image sensor device. In various other implementations, other semiconductor devices (including any disclosed herein) may be formed into a similar semiconductor package having a fanout structure as described herein. The use of the fanout structure in a package including only one device may provide for a smaller package size and greater flexibility in combining components within a larger device such as, by non-limiting example, a camera. The semiconductor package includes a semiconductor device 284 coupled to a second side of a semiconductor substrate 286. The device 284 may be coupled to the substrate 286 through an adhesive 288 such as a glue or a tape. The package illustrated includes three RDLs. The first RDL 290 is formed on a second side of the image sensor device 284 and may provide connection between the device and a substrate outside the package through an interconnect structure 296. The second RDL 292 and the third RDL 294 are coupled with pillars 298 extending through vias 300 formed through the substrate 286 of the image sensor device 284. The second 292 and third RDL 294 may provide electrically connectivity between various other portions of the semiconductor package.

As illustrated, the second RDL 294 is also coupled with an interconnect structure 302. The image sensor device 284 is encapsulated with a molding compound 304. The molding compound 304 is also coupled with the substrate 286 of the semiconductor package on a first side and the solder resist layer 306 on a second side. The solder resist layer 306 is formed on a second side of each of the molding compound 304 and image sensor device 284. The solder resist layer 306 is also formed around the RDL structures and the interconnect structures. In various implementations, the substrate of the semiconductor package may be any of the substrates described herein such as, by non-limiting example, silicon, gallium nitride, and a light transmissive material such as glass.

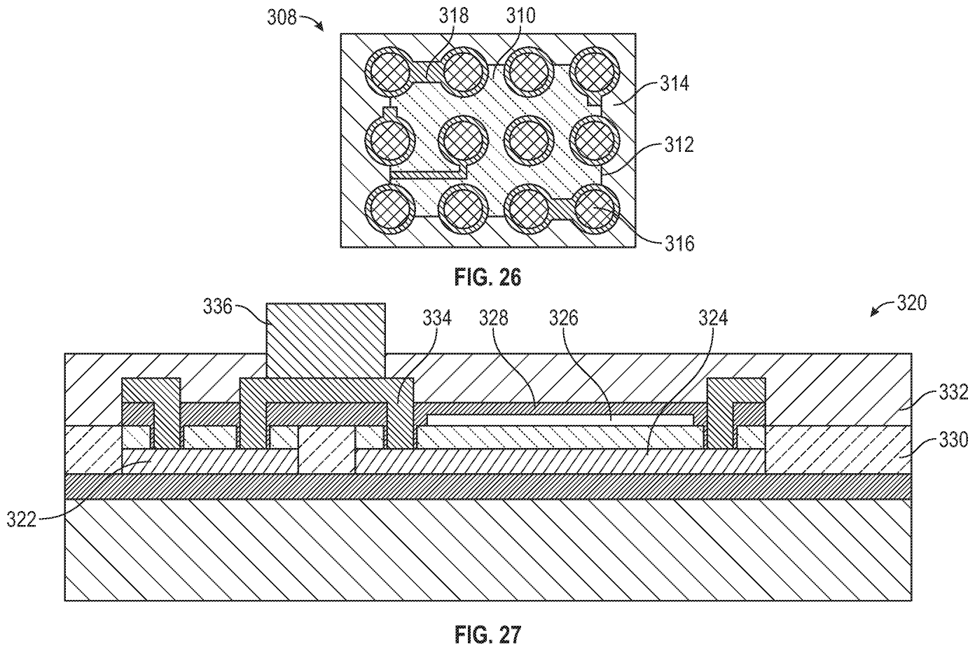

Referring to FIG. 26, a top view of the implementation of a semiconductor package 308 including a single device 310. In this view, the edges 312 of the image sensor device 310 are visible. The molding compound 314 is also visible extending around a perimeter of the image sensor device 310 and coupled with the substrate of the semiconductor package 308. A plurality of interconnect structures 316 are illustrated coupled with the image sensor device 310. In various implementations, the interconnect structures may include a ball grid array, solder balls, gold pillars, and other suitable electrically conductive material to couple the semiconductor package with other structures such as a printed circuit board. One or more of the RDL structures 318 are also visible extending between the interconnect structures 316 and extending to an edge of the device 310.

Referring to FIG. 27, another implementation of a semiconductor package 320 is illustrated. This implementation includes both a controller device 322 and an image sensor device 324 similar to other implementations described herein. In this implementation, however, the image sensor device includes a metal plate 326 within the package on a second side of the substrate 328 of the image sensor device 324. The metal plate 326 or shield may prevent light reflection on a second side of the image sensor device 324. In various implementation, the metal plate may be formed of, by non-limiting aluminum, titanium, combinations thereof, and other metals. The metal plate 324 may also be used in semiconductor packages as illustrated in FIG. 25. As illustrated, the package 320 also includes a molding compound encapsulating 330 the controller device 322 and the image sensor device 324. A solder resist 332 is formed over the molding compound 330 and around the RDLs 334 coupling the devices within the package. As illustrated, an interconnect structure 336 is coupled with the first RDL and extends to outside the package.

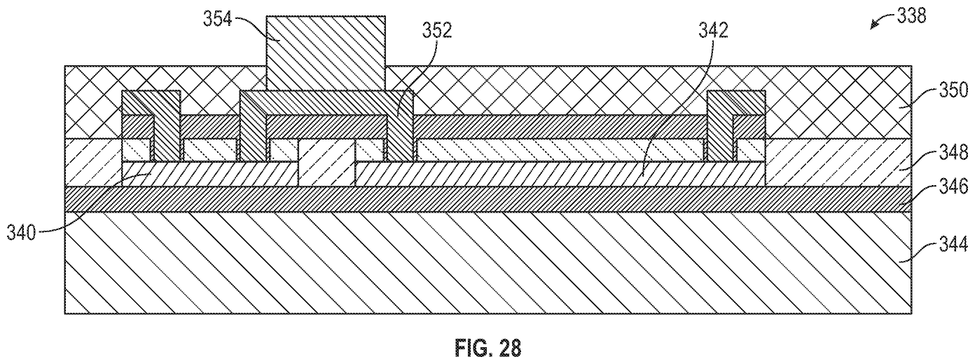

Referring to FIG. 28, another implementation of a semiconductor package 338 is illustrated. This implementation includes both a controller device 340 and an image sensor device 342. The image sensor device 342 and the controller device 340 are coupled to a second side of a substrate 344. The substrate 344 may be opaque or may include a light transmissive material. The image sensor device 342 and controller device 340 may be coupled to the substrate through a glue, a tape, or other suitable adhesive 346. A molding compound 348 is coupled with the second side of the substrate 344 around and between the devices 340 and 342. In this particular implementation, a black resist resin 350 is formed over and around the devices 340 and 342 and molding compound 348. The black resist resin 350 may protect the image sensor device 342 from back side reflection. In other implementations, other opaque or dark resin colors may be used in place of a solder resist. As illustrated, the resist resin is also formed around the RDL 352 coupling the devices within the package. The resist resin is also formed around the interconnect structure 354 which is coupled to the first RDL.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a substrate comprising a first side and a second side;
a semiconductor device and a controller device arranged in a same plane, wherein the semiconductor device and the controller device are coupled to the first side of the substrate through one of a tape or an adhesive;
a molding compound encapsulating the semiconductor device and the controller device;
a redistribution layer electrically coupling the semiconductor device and the controller device;
an interconnect structure coupled with the redistribution layer; and
a solder resist layer coupled around the interconnect structure and over the molding compound, the semiconductor device, the controller device, and the copper redistribution layer.

2. The semiconductor package of claim 1, wherein the substrate comprises an optically transmissive material.

3. The semiconductor package of claim 1, further comprising a second and a third redistribution layer.

4. The semiconductor package of claim 1, wherein the redistribution layer is copper.

5. The semiconductor package of claim 1, wherein the semiconductor device is an image sensor comprising one of a microlens or a color filter.

6. The semiconductor package of claim 1, further comprising one of a tape or a resin coating on a first side of the substrate.

7. The semiconductor package of claim 1, further comprising nickel gold (NiAu) plating around the interconnect structure.

8. A semiconductor package comprising:
a semiconductor device comprising a first side and a second side;
a controller device comprising a first side and a second side; and
a molding compound encapsulating the semiconductor device and the controller device;
a redistribution layer electrically coupling the semiconductor device and the controller device through two or more pillars on a second side of each of the semiconductor device and the controller device;
an interconnect coupled to the redistribution layer; and
a solder resist layer over the second side of each of the semiconductor device and the controller device;
wherein the controller device and the semiconductor device are in the same plane.

9. The semiconductor package of claim 8, further comprising a substrate coupled to the first side of each of the semiconductor device and the controller device.

10. The semiconductor package of claim 9, wherein the substrate comprises an optically transmissive material.

11. The semiconductor package of claim 8, further comprising a second and a third copper redistribution layer.

12. The semiconductor package of claim 8, wherein the redistribution layer is copper.

13. The semiconductor package of claim 8, wherein the semiconductor device is an image sensor comprising one of a microlens or a color filter.

14. The semiconductor package of claim 9, further comprising one of a tape or a resin coating on a first side of the substrate.

15. The semiconductor package of claim 8, further comprising nickel gold (NiAu) plating around the interconnect structure.

16. A method of forming a semiconductor package, the method comprising:
providing a substrate, the substrate comprising a first side and a second side;
coupling a first side of a semiconductor device to a second side of the substrate;
coupling a first side of a controller device to a second side of the substrate adjacent to the semiconductor device;
forming a molding compound on the second side of the substrate surrounding the semiconductor device and the controller device;
etching two or more via through a silicon layer on a second side of each of the semiconductor device and the controller device;
forming two or more pillars in the silicon layer in each of the semiconductor device and the controller device;
plating a redistribution layer between one of the two or more pillars on each of the semiconductor device and the controller device;
coupling an interconnect structure to the redistribution layer;
forming an insulation layer over the second side of each of the semiconductor device, the controller device, and the redistribution layer; and
dicing the substrate to form a plurality of semiconductor packages each including a semiconductor device and a controller device.

17. The method of claim 16, further comprising removing the substrate from a first side of each of the plurality of semiconductor packages.

18. The method of claim 16, wherein the two or more pillars and the redistribution layer comprise copper.

19. The method of claim 16, wherein dicing the substrate further comprises forming an optically transmissive lid over the semiconductor device and the controller device.

20. The method of claim 16, wherein the semiconductor device comprises an image sensor device.
